(19) United States
(12) Patent Application Publication
(10) Pub. No.: US 2006/0177987 A1
(43) Pub. Date: Aug. 10, 2006

(54) METHODS FOR FORMING THIN OXIDE LAYERS ON SEMICONDUCTOR WAFERS

(76) Inventor: Eric J. Bergman, Kalispell, MT (US)

Correspondence Address: PERKINS COIE LLP/SEMITOOL, PO BOX 1208, SEATTLE, WA, 98111-1208, US

(21) Appl. No.: 11/278,184

(22) Filed: Mar. 31, 2006

Related U.S. Application Data
(63) Continuation-in-part of application No. 10/631,376, filed on Jul. 30, 2003.
Application No. 10/631,376 is a continuation-in-part of application No. 09/621,028, filed on Jul. 21, 2000, now Pat. No. 6,869,487.
Application No. 10/631,376 is a continuation-in-part of application No. 08/853,649, filed on May 9, 1997, now Pat. No. 6,240,933.
Application No. 10/631,376 is a continuation-in-part of application No. PCT/US99/08516, filed on Apr. 16, 1999.
Application No. 10/631,376 is a continuation-in-part of application No. 09/061,318, filed on Apr. 16, 1998, now abandoned.
(60) Provisional application No. 60/145,350, filed on Jul. 23, 1999.
(60) Provisional application No. 60/125,304, filed on Mar. 19, 1999.
(60) Provisional application No. 60/099,067, filed on Sep. 3, 1998.

(51) Int. Cl. H01L 21/20; H01L 21/31

(52) U.S. Cl. 438/396; 438/787

(57) ABSTRACT

An oxide layer on a silicon wafer may be removed by applying a process chemical such as hydrofluoric acid to the wafer. This will typically remove substantially all of the existing oxide layer, leaving a bare silicon surface. A high quality self-terminating chemical oxide layer may then be grown on the wafer. The chemical oxide layer is then chemically etched to achieve a thinned oxide layer. A layer of material, which may be a high-K dielectric material, is than applied onto the thinned oxide layer. Microelectronic devices having improved electrical characteristics can be manufactured using this process.

### PRIORITY CLAIM

This application is a Continuation-in-Part of U.S. patent application Ser. No. 10/631,376 filed Jul. 30, 2003 and now pending, which is a Continuation-in-Part of U.S. patent application Ser. No. 09/621,028, filed Jul. 21, 2000 and now pending.

U.S. patent application Ser. No. 09/621,028 is:

a Continuation-in-Part of U.S. Patent Application No. 60/145,350 filed Jul. 23, 1999; and also

a Continuation-in-Part of U.S. patent application Ser. No. 08/853,649, filed May 9, 1997 and now U.S. Pat. No. 6,240,933; and also

a Continuation-in-Part and U.S. National Phase Application of International Application PCT/US99/08516, filed Apr. 16, 1999.

International Application PCT/US99/08516 is:

a Continuation-in-Part of U.S. Patent Application No. 60/125,304 filed Mar. 19, 1999; and also

a Continuation-in-Part of U.S. Patent Application No. 60/099,067 filed Sep. 3, 1998; and also

a Continuation-in-Part of U.S. patent application Ser. No. 09/061,318, filed Apr. 16, 1998. These applications are also incorporated herein by reference.

### BACKGROUND

The field of the invention is manufacturing semiconductor devices. Semiconductor devices are generally manufactured on silicon wafers, although other similar materials may also be used. Silicon is easily oxidized to form a silicon dioxide film or layer. Silicon dioxide, and other oxides, are electrical insulators. They are widely used in semiconductor devices. For example, an oxide layer is often used as a dielectric in the gate of microelectronic transistors, or as the dielectric material in a microelectronic capacitor or memory device. The electrical characteristics of the oxide material greatly affects the operational characteristics of the microelectronic devices.

At near ambient conditions, silicon will grow a self-limiting oxide layer a few molecular layers in thickness. This oxide is often referred to as a native oxide, meaning the oxide which will naturally grow on a silicon surface in an oxygen containing environment at near ambient conditions. The term “native oxide” is often used to refer to any silicon dioxide layer which will grow in an oxygen containing environment at ambient conditions, i.e., room temperature, air atmosphere, pressure, etc.

At ambient conditions, the native oxide layer may take several hours or days to grow. The resulting native oxide layer may contain contaminants, variations in quality and thickness, or varying electrical characteristics, depending on variations in the environment around the wafer during formation of the oxide layer. Consequently, to speed up the oxide formation process, provide more consistent results, and avoid airborne contaminants, for semiconductor manufacturing, silicon wafers are generally provided with a “chemical oxide” layer. The chemical oxide layer is created by exposing (usually bare) silicon wafers to an oxidizing chemical environment. This grows a “chemical oxide” layer on the silicon in a matter of minutes or seconds. The chemical oxide, and the native oxide, are both silicon dioxide. Indeed, the terms “chemical oxide” layer and “native oxide” layer are often used interchangeably. A “thermal oxide” layer generally refers to an oxide layer formed by heating the silicon wafer, either in air, or in an more oxidizing environment.

Whether the silicon dioxide layer is native or chemically grown, the layer is self limiting, i.e., it grows to a certain depth in the silicon, and then stops. Some researchers have proposed that the oxide layer is self-limiting to a specific thickness range due to dissociative chemisorption of molecular oxygen combined with silicon surface space-charge effects. See T. K. Whidden et al. “Initial oxidation of silicon (100): A unified chemical model for thin and thick oxide growth rates and interfacial structure”, Journal of Vacuum Science Technology, Vol. 13, No. 4, July/August 1995.

The precise thickness of an oxide layer may be difficult to determine. Attempts to measure the layer thickness can be problematic, even when using state of the art measuring equipment. However, most researchers today agree that the native or chemical silicon dioxide oxide layer is in the range of 8-12 angstroms, or about 5 molecular layers (±1) thick.

As the semiconductor industry has achieved remarkable success in making increasingly smaller devices, more and more often, even the 8-12 angstrom thick native, chemical or thermal oxide layer is too thick to provide desired device performance. For example, with the use of “high-K” dielectric materials, device performance may be degraded because the underlying oxide layer is too thick to provide the desired dielectric properties. High-k dielectric layer materials may include hafnium oxide, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, and lead zinc niobate. Hafnium oxide, zirconium oxide, and aluminum oxide may often be used.

Although it is possible to fully remove the silicon dioxide layer using a process chemical such as hydrofluoric acid (HF), in general high-K materials do not adhere well to the underlying bare silicon. Fully removing the silicon dioxide layer also leaves no dielectric layer. Accordingly, removing the silicon dioxide layer entirely has not provided beneficial results. Ideally, the high-K material would be deposited on a high quality native, chemical or thermal oxide layer of about one half of the usual thickness, i.e., from about 3 to 6 angstroms. Unfortunately, growing an oxide layer to this level of precision is generally not achievable with current technologies. As the formation of the oxide layer is affected by factors such as chemisorbtion of oxygen, and space-charge effects, the resulting oxide layer will generally have a thickness of 6-15 angstroms, notwithstanding efforts to grow a thinner layer. Accordingly, challenges remain in providing sufficiently thin oxide layers on silicon wafers and similar substrates.

### SUMMARY

The inventor has now discovered ways to provide very thin oxide layers on silicon wafers and other substrates. Recognizing that it is difficult or impossible to control actual growth of thin oxide films, the inventor has solved the oxide layer thickness problem with a new process using an entirely different approach. In this new process, rather than trying to control the oxide layer growth, the oxide layer is allowed to grow without restraint. Attempts to limit the growth are not needed. After the oxide layer is grown, it is then etched back down to a desired thickness.

In this new process, the existing or initial oxide layer on the wafer, which may be of varying quality, may be removed by applying a process chemical to the wafer. This will typically remove substantially all of the initial oxide layer from the wafer, leaving a bare silicon surface. A high quality self-terminating chemical oxide layer may then grown on the wafer. The chemical oxide layer is then chemically etched to achieve a thinned oxide layer. A fluorinated process chemical, such as hydrofluoric acid, may be used to remove the initial oxide layer as well as to etch the subsequently grown chemical oxide layer to produce the thinned oxide layer.

The thinned oxide layer may eventually re-grow to its native terminal thickness. However, this re-growth, especially in a dry and non-oxidizing environment, requires significant time to occur. Consequently, the wafer may be further processed, before the thinned oxide layer grows thicker. Hence the desired dielectric properties of the devices formed on the thinned oxide film may be achieved. Apart from use with high-K dielectric materials, the process is also applicable to the growth and/or deposition of gate dielectrics, metal deposition, growth of epitaxial films, etc.

### BRIEF DESCRIPTION OF THE DRAWINGS

FIG. 1 shows a schematic illustration of a system which may be used to perform the methods described. Other equivalent systems may also be used.

### DETAILED DESCRIPTION OF THE DRAWINGS

Silicon wafers as supplied to the semiconductor device fabrication facility or “fab” often have a native silicon dioxide surface layer or film. This film is formed via the oxidation of silicon by oxygen in the environment over a relatively long time. No specific process step is used or needed to form the native silicon oxide layer. It forms by itself simply by exposure of the wafer to air. The formation of the native silicon oxide layer is expressed as:
Si+O2→SiO2

Silicon wafers may also be provided with a chemical oxide layer. The chemical oxide layer is also silicon dioxide. However, the chemical oxide layer is formed by actively exposing the wafer to an oxidizer such as oxygen or ozone in a controlled environment. A thermal oxide layer may be formed by heating a silicon wafer, in the presence of air or another oxidizer, usually in a controlled environment such as a process chamber. The present process may be used on silicon wafers having native, chemical or thermal oxide layers. As used here, the term “initial oxide layer” means whatever starting or original silicon oxide layer is on the wafer. The initial oxide layer may be a native oxide layer, a chemical oxide layer, or a thermal oxide layer, or a combination of them. The present process may be used to provide a silicon oxide layer having a known thickness, and/or a thickness less than the thickness of the initial oxide layer.

If the initial oxide layer is considered to be of sufficiently high quality for its desired purpose, the following first and second steps of the process may be omitted, with the third step and optionally the fourth step described below performed directly. If the initial oxide layer is not of sufficiently high quality, then the first and second steps below may also performed in sequence, and before the third step described below.

First Step: Removing the Initial Oxide Layer.

This first step is performed to remove the initial oxide layer. Although it may be performed in different ways, typically the initial oxide layer is removed by applying a fluorinated process chemical to the wafer. The fluorinated process chemical is most often HF although other fluorinated process chemicals, for example ammonium fluoride, may be used. For purpose of description, the following explanation of the process refers to use of HF as the fluorinated process chemical. The HF can be applied as a liquid (HF in de-ionized water) by immersion or by spraying. For example, a 100:1 water to HF liquid dilution may be used to remove the initial oxide layer relatively quickly (starting with a %49 HF solution from the manufacturer). HF may also be applied by delivering HF vapor into a process chamber, where the HF mixes with water. An HF plasma may also be used.

Second Step.

If the first step above is performed, the initial oxide layer has been removed leaving the wafer with an essentially bare silicon surface. This second step is then performed to grow a high quality chemical oxide layer, in a controlled environment. As a result, defects in the initial oxide layer, which may have grown under uncontrolled conditions, are removed.

The chemical oxide layer may be formed by exposing the wafer to an oxidizer under controlled conditions. The wafer generally is placed in a process chamber. Potential for contamination during formation of the chemical oxide layer is therefore reduced. An oxidizer is provided into the process chamber. The oxidizer may be dry ozone gas. Ozone gas in combination with water may also be used. The ozone may be dissolved or entrained in the water. Hydrogen peroxide or oxidizing acids may also be used as an oxidizer. The wafer may alternatively be immersed into a oxidizing liquid. The oxidizer oxidizes the surface of the wafer to form a chemical (or chemically initiated) silicon oxide layer. The concentrations of the oxidizer, time duration of exposure, temperature, etc. are controlled so that a uniform high quality silicon dioxide layer is formed. This chemical oxide layer grows until it reaches its self-terminating thickness. Since a chemical oxidizer is used, the chemical oxide layer is completely formed in a matter of seconds or minutes. A thermal oxide layer may be created in place of a chemical oxide layer, although a chemical oxide layer will generally be more suitable in performing the process.

If using a liquid oxidizer, the wafer may be rotated in the process chamber, while the liquid oxidizer is applied to the wafer. Rotation helps to distribute the liquid in a liquid layer across the wafer surface, and may be used to help to control the thickness of the liquid layer. Ozone gas may then diffuse through the liquid layer to the wafer surface. The chamber and/or the liquid may be heated. Spraying may also be used to apply the liquid and to help form the liquid into a layer. Surfactants may also optionally be used.

Third Step.

In the third step, the chemical oxide layer formed in the second step is etched to thin it down to a desired dimension. Alternatively, if the initial oxide layer is sufficient, and steps 1 and 2 have been skipped, then the initial oxide layer is thinned, as described below. In either case, the initial oxide layer or the chemical oxide layer, each having a thickness in the range of 8-12 angstroms, is etched to provide a thinned oxide layer, with the objective of providing an oxide layer in the range of about 4-6 angstroms thick.

This step may be performed by applying a fluorinated process chemical onto the oxide layer. The fluorinated process chemical may be the same as those described in first step above, and it may also be applied as described in first step. However, the process is easier to control if the fluorinated process chemical used in this step is more highly dilute, to provide a slow etch rate. For example, a dilution of 200-500:1 of water to HF solution may be used. Since only a smaller amount of oxide is etched, a slower etch rate provided by a more dilute etchant liquid improves control of the process. The etch rate will typically be about 0.5 to about 5 angstroms/minute. The duration of the etch will typically range from about 1-10 minutes.

Since accurately measuring such thin layers tends to be difficult, the process parameters (chemical selection, concentration, flow rate, temperature, duration, etc.) can be established empirically and via testing of actual microelectronic devices formed on oxide layers produced under varying experimental conditions.

Fourth Step.

The wafer now having the thinned oxide layer is ready for a subsequent manufacturing step. This next step may be application of a high-K material onto the thinned oxide layer, or it may involve applying a different material. This step will generally be performed promptly, e.g., within 30, 60, 120, or 480 minutes, after the thinned oxide layer is formed. By applying another material (whether a high-K material, a metal layer, or another dielectric layer) onto the thinned oxide layer, further growth of the oxide layer is prevented, since no additional oxidizer can penetrate into the wafer. If this step is not performed promptly after step 3 above, the wafer may be stored in a non-oxidizing environment to better preserve the thinned oxide layer. For example, the wafer may be placed in a sealed wafer container purged with nitrogen.

Example of a Processing System.

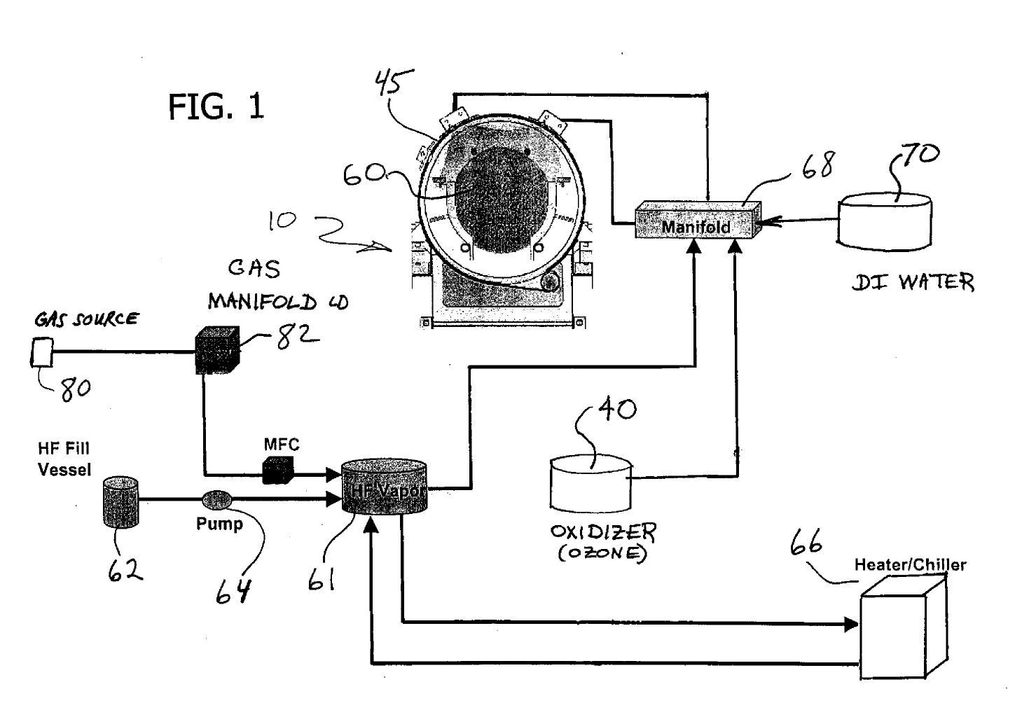

The process described above may be carried out in one or more different types of apparatus. FIG. 1 is a schematic flow diagram of one example of a processing system 10 which may be used. In operation, one or more wafers 60 are loaded into a wafer holder or rotor in a process chamber 45, which may be a batch processor or a single wafer processor. The wafers 60 may be loaded manually or by a robot. The wafers 60 may be handled or contacted directly by the robot or rotor. Alternatively, the wafers 60 may be handled within a carrier tray or cassette, which is placed into the rotor or other holder. Once the wafers 60 are loaded into the processor, the process chamber 45 is preferably closed, and may optionally form a fluid-tight seal.

HF vapor is provided into the process chamber 45 to etch away and remove the initial oxide layer on the wafers. To generate the HF vapor, HF liquid may be provided in an HF fill vessel 62, and then pumped into an HF vaporizer 61 with a pump 64. The HF vaporizer 61 can be connected to a heat exchanger 66, to heat to the HF vaporizer 61 to convert the HF liquid into HF vapor. In general, the vapor may be generated as described in U.S. Pat. No. 6,162,734, incorporated herein by reference. The HF vapor generated by the vaporizer is then provided into the process chamber, optionally via the vapor delivery manifold 68.

The HF vapor may be mixed with a carrier gas, such as nitrogen (N2) gas, for delivering the HF vapor into the process chamber 45, as is common in the semiconductor wafer manufacturing industry. N2 gas, or a gas with similar properties, may also be delivered to the process chamber 45 after the wafers 60 are processed, in order to purge any remaining HF vapor from the process chamber 45 before the chamber door is opened. The use of HF vapor in conjunction with a carrier gas, is described in U.S. Pat. Nos. 5,954,911 and 6,162,735, incorporated herein by reference.

The carrier gas may be delivered from a gas source 80 into gas manifold 82, through a mass flow controller (MFC) 84, and into the HF vaporizer 61. The MFC controls the mass of the carrier gas that flows to the other system components. The carrier gas passes through the HF vaporizer 61, where it entrains the HF vapor and carries the HF vapor to the process chamber 45. To generate the HF vapor, the carrier gas may be bubbled through the HF solution in the HF vaporizer 61, or may be flowed across the surface or the HF solution, becoming enriched in HF and water vapor. Alternatively, the HF vapor may be generated by heating or sonically vaporizing the HF solution. While FIG. 1 shows various components, the process requires only a source of a process chemical which can remove the initial oxide layer and then grow a chemical or thermal oxide layer (if desired), and then etch the chemical or thermal oxide layer down to a desired thickness. Accordingly, FIG. 1 shows various elements as they might be used in a typical system, although each of these elements is not essential and may be omitted.

Referring still to FIG. 1, the HF vapor enters the process chamber and etches and removes the initial silicon dioxide film on the wafers 60. The HF vapor reacts with the silicon dioxide to form silicon tetrafluoride (SiF4), which may then be evolved as a gas and removed via a system exhaust, or may be dissolved in an aqueous carrier liquid. The silicon dioxide dissolution reaction generally proceeds as follows:
4HF+SiO2→SiF4+2H2O

When HF is used in vapor form, as in this example, no rinsing or drying step is required, although rinsing and drying may be used if desired. Additionally, only a minimal amount of HF and carrier gas is needed.

In an alternative embodiment, HF is delivered into the process chamber as an anhydrous gas. Anhydrous HF gas does not generally produce a significant etch rate on silicon dioxide films. However, for this application, a very low etch rate may be acceptable. Consequently, anhydrous HF may be used as a pure gas or diluted with another gas to perform the etch. In order for the etch rate to become significant for most applications, the anhydrous HF gas may be mixed with water so that it is no longer anhydrous. The presence of water or water vapor appears to catalyze the reaction. The absence of water results in a low etch rate on silicon dioxide. Thus, the anhydrous HF gas is preferably either mixed with water or water vapor prior to delivery to the wafer surface, or mixed with an aqueous layer on the wafer surface. Water may be sprayed or otherwise provided into the chamber 45 from a water source 70. Alternatively, anhydrous HF may be mixed with an organic liquid or vapor to form either a microscopic or macroscopic liquid film on the wafer and thereby enhance the etch rate. Various compounds may be used as an organic liquid including, but not limited to, organic acids such as acetic acid, alcohols such as 2-propanol, methanol or ethanol or compounds such as n-methyl pyrolidone.

In another embodiment, deionized (DI) water at a controlled temperature is sprayed onto a wafer surface simultaneously with the delivery of anhydrous HF gas into the process chamber. The anhydrous HF gas dissolves in the DI water, causing the anhydrous HF gas to become aggressive toward the silicon dioxide on the wafer surface. The anhydrous HF gas, mixed with water, etches the silicon dioxide film on the wafer surface. The etch product (SiF4) may then be evolved as a gas and removed via a system exhaust, or may be dissolved in an aqueous carrier liquid,

The anhydrous HF gas may alternatively be bubbled into water, or mixed with a water vapor or aerosol, within the processing chamber, or prior to entering the processing chamber. In the latter cases, HF vapor is generated by mixing anhydrous HF gas with water vapor. The anhydrous HF gas may also be mixed with ozone before being delivered into the process chamber.

In another embodiment, HF may be delivered into the process chamber as an aqueous solution. The HF solution may have other additives such as ammonium fluoride as a buffer, organic solvents such as ethylene glycol to help promote surface wetting and control ionization, or other commonly used additives. HF and water, however, are preferably the key components to the solution. In each of the embodiments, rinsing and drying may optionally be used after one or more of the steps is completed.

Referring still to FIG. 1, after the initial oxide layer has been removed, the chemical oxide layer is grown by providing an oxidizer, such as ozone, into the chamber 45, from an oxidizer source or generator 40. The oxidizer may be in liquid or gas phase. After the chemical oxide layer is grown, the flow of oxidizer is turned off, and the chamber purged of oxidizer. HF is then re-introduced into the chamber, optionally in a more dilute form, and the chemical oxide layer is etched down to a desired thickness. The wafer is generally then removed from the chamber and moved to another process station where a layer of material, e.g., a high-K material, is applied onto the thin chemical oxide layer.

The processes described may be performed in a single wafer process mode, or in a batch mode, with multiple wafers processed simultaneously in a batch. The wafer(s) may be rotated at times during processing, on a turntable or in a rotor. Rotation helps to distribute liquid across the wafer surface. Process temperatures may vary from below ambient up to 99° C. Similarly, process chamber pressure may be at ambient, or up to 2, 3, 4 or 5 times ambient pressure. Partial vacuum conditions may also be used in the process chamber.

While the term wafer as used here generally refers to silicon or semiconductor wafers, it also encompasses similar flat media articles or workpieces which may not be silicon or a semiconductor, but which may have an oxide layer.

While embodiments and applications of the present invention have been shown and described, it will be apparent to one skilled in the art that other modifications are possible without departing from the inventive concepts herein. The invention, therefore, is not to be restricted except by the following claims and their equivalents.

What is claimed is:

1. A method for forming an oxide layer on a silicon wafer, comprising:
A] applying a first fluorinated process reagent to the wafer, with the fluorinated process agent acting to remove silicon dioxide from the wafer;
B] growing a self-terminating chemical oxide layer on the wafer;
C] applying a second fluorinated process reagent to the chemical oxide layer on the wafer to reduce the thickness of the chemical oxide layer; and
D] applying a layer of material over the chemical oxide layer.

2. The method of claim 1 wherein one or both of the first and second fluorinated process reagents comprises HF.

3. The method of claim 2 wherein one or both of the first and second fluorinated process reagents comprises HF liquid, vapor or plasma.

4. The method of claim 2 wherein one or both of the first and second fluorinated process reagent comprises ammonium fluoride.

5. The method of claim 2 wherein one or both of the first fluorinated process reagents is sprayed onto the wafer.

6. The method of claim 2 wherein one of both of the first fluorinated process reagents is applied by immersing the wafer into a liquid bath of the first fluorinated process reagent.

7. The method of claim 1 wherein the self-terminating chemical oxide layer on the wafer is grown in a controlled environment.

8. The method of claim 7 wherein the controlled environment comprises a process chamber, with dry ozone gas provided into the process chamber.

9. The method of claim 7 wherein the controlled environment comprises a process chamber, with ozone gas provided into the process chamber with de-ionized water.

10. The method of claim 9 wherein the ozone gas is dissolved or entrained in the water.

11. The method of claim 9 with dry ozone gas provided into the process chamber and diffusing through a layer of liquid, including de-ionized water, on the wafer surface.

12. The method of claim 7 wherein the controlled environment comprises a process chamber, with an oxidizer provided into the process chamber.

13. The method of claim 12 wherein the oxidizer comprises hydrogen peroxide or an oxidizing acid.

14. The method of claim 1 wherein the second fluorinated process reagent comprises HF and a liquid selected from the group consisting of de-ionized water, ascetic acid and an alcohol.

15. The method of claim 1 wherein the second fluorinated process reagent etches the oxide layer at an etch rate of from about 0.5 to 5 angstroms per minute.

16. The method of claim 1 wherein the second fluorinated process reagent is applied for an empirically determined time interval.

17. The method of claim 1 wherein the layer of material comprises a high-K dielectric material.

18. The method of claim 17 wherein the high-K dielectric material comprises a member selected from the group consisting of hafnium, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, and lead zinc niobate.

19. A method for forming a reduced thickness oxide layer on a silicon wafer having an initial self terminating native, thermal or chemical oxide layer, comprising:
determining the thickness of the initial oxide layer on the wafer;
applying a fluorinated process reagent to the initial oxide layer on the wafer for a time interval sufficient to thin the initial oxide layer by a desired amount; and
applying a layer of material onto the thinned oxide layer.

20. The method of claim 19 wherein the thickness of the initial oxide layer is determined by allowing the wafer to grow a native oxide layer having a known terminal thickness.

21. The method of claim 19 wherein the thickness of the initial oxide layer is determined by measuring.

22. The method of claim 19 wherein the thickness of the initial oxide layer is provided by the wafer manufacturer.

23. The method of claim 19 wherein the time interval is empirically selected.

24. The method of claim 19 wherein the layer of material is applied within 24 hours of thinning the initial oxide layer.

25. The method of claim 19 further comprising storing the wafer in a non-oxidizing environment after thinning the initial oxide layer and before applying the layer of material to the thinned initial oxide layer.

26. A method of manufacturing a microelectronic device on a silicon wafer comprising:
applying a first fluorinated process reagent to the wafer, with the fluorinated process agent acting to remove a silicon dioxide film, having a thickness T1, from the wafer;
growing a self-terminating chemical oxide layer on the wafer by exposing the wafer to an oxidizer;
applying a second fluorinated process reagent to the chemical oxide layer on the wafer, with the second fluorinated process reagent etching the chemical oxide layer down to a thickness T2, with T2 less than T1; and
applying a high-K dielectric material on the chemical oxide layer.
